(19) United States
(12) Patent Application Publication
(10) Pub. No.: US 2022/0413014 A1
(43) Pub. Date: Dec. 29, 2022

(54) JIG

(71) Applicant: YOKOWO CO., LTD., Kita-ku, Tokyo (JP)

(72) Inventors: Daisuke HOSOKAWA, Tomioka-Shi, Gunma (JP); Shunsuke KOBAYASHI, Tomioka-Shi, Gunma (JP); Ken KAWAMURA, Tomioka-Shi, Gunma (JP)

(73) Assignee: YOKOWO CO., LTD., Kita-ku, Tokyo (JP)

(21) Appl. No.: 17/778,862

(22) PCT Filed: Sep. 7, 2020
(86) PCT No.: PCT/JP2020/033792

§ 371 Date: May 23, 2022

(30) Foreign Application Priority Data
Nov. 26, 2019 (JP) 2019-212967

(51) Int. Cl. G01R 1/073; G01R 1/067

(52) U.S. Cl. CPC G01R 1/0735; G01R 1/06711; G01R 31/2886

(57) ABSTRACT

A jig (30) includes a first block portion (100) at which a probe head (300) is installed, and a first suction port (112) formed on the first block portion (100). Air present on a side where one end of a probe (330) provided in the probe head (300) is located is sucked from the first suction port (112).

### TECHNICAL FIELD

The present invention relates to a jig.

### BACKGROUND ART

For example, as disclosed in Patent Document 1, a probe head may be used for electrical inspection of an electronic device such as an integrated circuit (IC) and the like. The probe head is provided with a probe. The probe head includes a pin plate and a pin block. The probe penetrates each stepped hole in the pin plate and pin block.

### RELATED DOCUMENT

### Patent Document

[Patent Document 1] Japanese Unexamined Patent Publication No. 2019-90760

### SUMMARY OF THE INVENTION

### Technical Problem

In a case where the probe provided on the probe head is replaced, the pin plate may be detached from the pin block. If a plunger of the probe on the pin plate side is tilted, the plunger of the probe on the pin plate side may get caught in the pin plate and the probe may be moved together with the pin plate. This case results in a situation where the probe may be detached from a pin block together with the pin plate, a situation where the probe detached from the pin block may fall between a probe and a probe on the pin block side, or the like. For example, when the probe is detached from the pin block together with the pin plate, a probe not to be replaced is also detached from the pin block, and extra work is required to return the probe not to be replaced to the pin block. If the probe detached from the pin block falls between the probe and the probe on the pin block side, work of taking out the fallen probe may be troublesome. Accordingly, the above situation may be an obstacle to the probe replacement work.

An example of an object of the present invention is to facilitate replacement of probes. Other objects of the invention will become apparent from the description of the present specification.

### Solution to Problem

An aspect of the present invention is a jig including a first block portion at which a probe head is installed; and a first suction port formed on the first block portion, in which air present on a side where one end of a probe provided in the probe head is located is sucked from the first suction port.

### Advantageous Effects of Invention

According to the above aspect of the present invention, a probe can be easily replaced.

### BRIEF DESCRIPTION OF THE DRAWINGS

FIG. 1 is an exploded perspective view of a jig according to an embodiment.

FIG. 2 is an exploded perspective view of a probe head shown in FIG. 1.

FIG. 3 is a perspective view of a pin block shown in FIG. 2 as viewed from a viewpoint opposite to a viewpoint in FIG. 2.

FIG. 4 is a perspective view of an upper jig shown in FIG. 1 as viewed from a viewpoint opposite to a viewpoint in FIG. 1.

FIG. 5 is a diagram for describing an example of an operation of the jig shown in FIG. 1.

FIG. 6 is a diagram for describing an example of an operation of the jig shown in FIG. 1.

### DESCRIPTION OF EMBODIMENTS

Hereinafter, embodiments of the present invention will be described with reference to the drawings. In all drawings, similar constituents are given the same reference numerals, and description thereof will not be repeated as appropriate.

In the present specification, ordinal numbers such as “first”, “second”, and “third” are added only for the purpose of distinguishing constituents having similar names unless otherwise specified, and do not mean a particular feature (for example, order or importance) of a constituent.

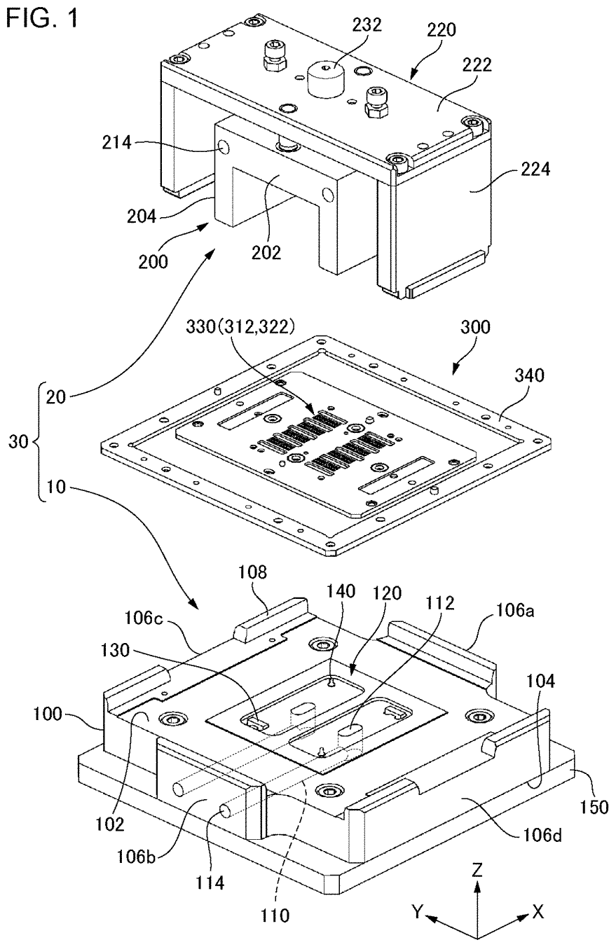

FIG. 1 is an exploded perspective view of a jig 30 according to an embodiment.

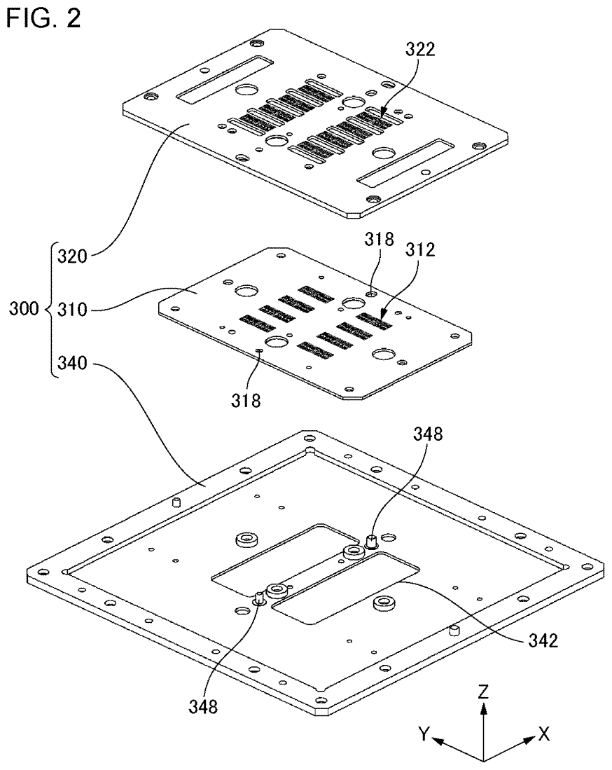

In FIG. 1, a first direction X is a length direction of the jig 30. A positive direction (a direction indicated by an arrow attached to the first direction X) of the first direction X is a direction from a second side surface 106b toward a first side surface 106a of a first block portion 100 described later. A negative direction (a direction opposite to the direction indicated by the arrow attached to the first direction X) of the first direction X is a direction from the first side surface 106a toward the second side surface 106b of the first block portion 100 described later. A second direction Y is orthogonal to the first direction X and is a width direction of the jig 30. A positive direction (a direction indicated by the arrow attached to the second direction Y) of the second direction Y is a direction from a fourth side surface 106d toward a third side surface 106c of the first block portion 100 described later. A negative direction (the direction opposite to the direction indicated by the arrow attached to the second direction Y) of the second direction Y is a direction from the third side surface 106c toward the fourth side surface 106d of the first block portion 100 described later. A third direction Z is orthogonal to both the first direction X and the second direction Y, and is a height direction of the jig 30. A positive direction (the direction indicated by the arrow attached to the third direction Z) of the third direction Z is a direction (upward direction) from a second surface 104 to a first surface 102 of the first block portion 100 described later. A negative direction (a direction opposite to the direction indicated by the arrow attached to the third direction Z) of the third direction Z is a direction (downward direction) from the first surface 102 to the second surface 104 of the first block portion 100 described later. In FIGS. 2 to 6 that will be described later, directions are the same as those in FIG. 1.

The jig 30 includes a lower jig 10 and an upper jig 20. The lower jig 10 has the first block portion 100 and a pedestal portion 150. The upper jig 20 has a second block portion 200 and a support block portion 220.

The first block portion 100 has the first surface 102, the second surface 104, the first side surface 106a, the second side surface 106b, the third side surface 106c, and the fourth side surface 106d.

The first surface 102 is an upper surface of the first block portion 100. The second surface 104 is a surface opposite to the first surface 102 and is a lower surface of the first block portion 100. The first side surface 106a, the second side surface 106b, the third side surface 106c, and the fourth side surface 106d are located between the first surface 102 and the second surface 104. The first block portion 100 has a protruding portion protruding from a central portion of the first block portion 100 in the second direction Y toward the positive direction of the first direction X. The first block portion 100 has another protruding portion protruding from the central portion of the first block portion 100 in the second direction Y toward the negative direction of the first direction X. The third side surface 106c and the fourth side surface 106d are flat when viewed from the direction (third direction Z) perpendicular to the first surface 102 or the second surface 104 of the first block portion 100. However, a shape of the first block portion 100 is not limited to the shape according to the present embodiment.

The first block portion 100 has a raised portion 108 protruding from the first surface 102 of the first block portion 100 toward the positive direction of the third direction Z. The raised portion 108 extends along a region surrounding the probe head 300 when the probe head 300 is installed at the first block portion 100. Accordingly, the raised portion 108 may function as a guide member for guiding the probe head 300 to an appropriate position with respect to the first block portion 100.

In the present embodiment, the raised portion 108 intermittently extends along a region surrounding the probe head 300 when the probe head 300 is installed at the first block portion 100. In other words, a part of the raised portion 108 is broken when viewed from above the first surface 102 of the first block portion 100 (the positive direction of the third direction Z). In the present embodiment, the raised portion 108 is broken at both end portions of the first side surface 106a, both end portions of the second side surface 106b, the central portion of the third side surface 106c, and the central portion of the fourth side surface 106d. Accordingly, a user of the jig 30 can easily finger the probe head 300 at the position where the raised portion 108 is broken, and thus it is possible to improve the efficiency of work such as installing the probe head 300 at the first block portion 100 or detaching the probe head 300 from the first block portion 100. A second arm 224 of the second block portion 200 (details are described later) can be installed at the position where the raised portion 108 is broken, and the raised portion 108 can be prevented from interfering with the second arm 224 of the second block portion 200. In the present embodiment, the second arm 224 of the second block portion 200 can be installed at the central portion of the third side surface 106c and the central portion of the fourth side surface 106d. However, a position where the second arm 224 of the second block portion 200 is installed is not limited to the position according to the present embodiment.

A shape of the raised portion 108 is not limited to the shape according to the present embodiment. For example, the raised portion 108 may continuously extend along a region surrounding the probe head 300 when the probe head 300 is installed at the first block portion 100. In other words, the raised portion 108 may not be broken at any portion of the region surrounding the probe head 300 when the probe head 300 is installed at the first block portion 100.

In the present embodiment, the raised portion 108 extends along an outer edge of the probe head 300 (a frame 340 described later). However, for example, in a case where the frame 340 is not provided, the raised portion 108 may extend along an outer edge of the pin plate 320 (for example, FIG. 2 described later).

A recess 120 is formed on the first surface 102 of the first block portion 100. In the present embodiment, two recesses 120 are formed on the first surface 102 of the first block portion 100. The two recesses 120 are arranged along the second direction Y and extend along the first direction X. However, the number, shape, and arrangement of the recesses 120 are not limited to this. For example, the number of recesses 120 may be only one, or may be three or more. That is, at least one recess 120 may be formed on the first block portion 100. Alternatively, the recess 120 may not be formed on the first block portion 100.

A first suction port 112 is formed on a portion of the first block portion 100 defining the bottom surface of the recess 120. The first suction port 112 communicates with a first opening 114 formed on the first side surface 106a of the first block portion 100 through a first ventilation path 110 formed inside the first block portion 100. The first opening 114 is connected to a decompression regulator (not shown). Accordingly, when air is sucked by the decompression regulator, the air present (located) on the side where one end (lower end) in the third direction Z of the probe 330 provided in the probe head 300 is located is sucked from the first suction port 112. When the probe head 300 is warped in a case where the recess 120 is not formed (for example, when the probe head 300 is warped to enter the recess 120 if the recess 120 is formed), a gap between the first block portion 100 and the probe head 300 may be large. In contrast, in a case where the recess 120 is formed, this gap can be reduced. Accordingly, compared with a case where the recess 120 is not formed, air present (located) on the side where one end (lower end) in the third direction Z of the probe 330 provided in the probe head 300 is located can be efficiently sucked.

A position of the first suction port 112 is not limited to the position according to the present embodiment. For example, the first suction port 112 may be formed on a portion of the first block portion 100 defining the inner side surface of the recess 120. Alternatively, in a case where the recess 120 is not formed on the first surface 102, the first suction port 112 may be formed on the first surface 102 where the recess 120 is not formed.

A flexible member 130 is provided on a portion of the first block portion 100 defining the bottom surface of the recess 120. That is, the flexible member 130 is provided in a region facing the probe head 300 when the probe head 300 is installed at the first block portion 100. The flexible member 130 is, for example, a gel sheet. A height of the flexible member 130 in the third direction Z is larger than a depth of the recess 120 in the third direction Z. Accordingly, when the probe head 300 is installed on the first surface 102 of the first block portion 100, the probe head 300 is in contact with the flexible member 130. Accordingly, when the air present (located) on one side (lower side) of the probe head 300 in the third direction Z is sucked from the first suction port 112, the flexible member 130 is pressed by the probe head 300 in the third direction Z. Thus, the first block portion 100 and the probe head 300 can be brought into close contact with each other. Accordingly, except for the recess 120, a gap is less likely to occur between the first block portion 100 and the probe head 300. Thus, it is possible to suppress the suction of air from the gap between the first block portion 100 and the probe head 300. Thus, compared with a case where the flexible member 130 is not provided, the air present (located) on the side where one end (lower end) in the third direction Z of the probe 330 provided in the probe head 300 is located can be efficiently sucked.

A position of the flexible member 130 is not limited to the position according to the present embodiment. For example, in a case where the recess 120 is not formed on the first surface 102, the flexible member 130 may be formed on the first surface 102 where the recess 120 is not formed. That is, the flexible member 130 may be provided in a region facing the probe head 300 when the probe head 300 is installed at the first block portion 100. In this case, the flexible member 130 is in contact with the probe head 300 installed at the first block portion 100. Thus, as described above, air present (positioned) on the side where one end (lower end) in the third direction Z of the probe 330 provided in the probe head 300 is located can be efficiently sucked.

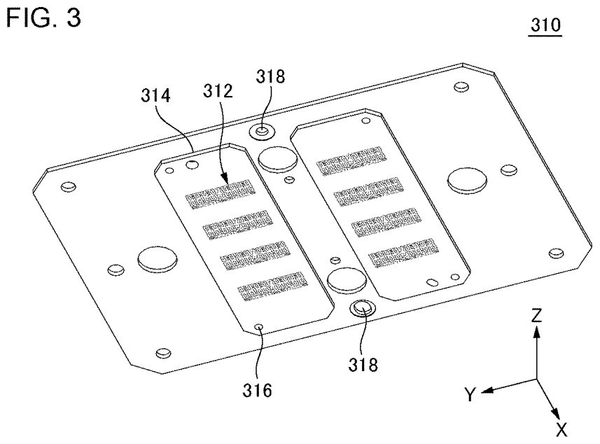

A projection 140 is provided on a portion of the first block portion 100 defining the bottom surface of the recess 120. That is, the projection 140 is provided in a region facing the probe head 300 when the probe head 300 is installed at the first block portion 100. The projection 140 protrudes upward (the positive direction of the third direction Z) of the first surface 102 of the first block portion 100. When the probe head 300 is installed at the first block portion 100, the projection 140 of the first block portion 100 is inserted into a hole 316 (for example, FIG. 3 described later) of the pin block 310 of the probe head 300. Accordingly, the projection 140 may function as a guide member for guiding the probe head 300 to an appropriate position with respect to the first block portion 100.

A position of the projection 140 is not limited to the position according to the present embodiment. For example, in a case where the recess 120 is not formed on the first surface 102, the projection 140 may be formed on the first surface 102 where the recess 120 is not formed. That is, the projection 140 maybe provided in a region facing the probe head 300 when the probe head 300 is installed at the first block portion 100. In this case, the projection 140 is inserted into the probe head 300 installed at the first block portion 100. Accordingly, as described above, the projection 140 may function as a guide member for guiding the probe head 300 to an appropriate position with respect to the first block portion 100.

In the present embodiment, the first block portion 100 is made of resin. In this case, a cutting process for the first ventilation path 110, the first suction port 112, the first opening 114, and the recess 120 becomes easier compared with a case where the first block Portion 100 is made of, for example, metal. However, a material forming the first block portion 100 may be any material having a hardness such that it is not deformed by suction of air by the decompression regulator, and may be, for example, metal instead of resin.

The first block portion 100 is installed on a pedestal portion 150. For example, the first block portion 100 is fixed to the pedestal portion 150 by a fixing tool such as a screw. The density of a material (for example, metal) forming the pedestal portion 150 is higher than the density of a material (for example, resin) forming the first block portion 100. Accordingly, even if the first block portion 100 is made of a relatively lightweight material such as resin, the lower jig 10 can be stably installed on the installation surface of the lower jig 10 due to the high weight of the pedestal portion 150. However, the method of stably installing the lower jig 10 on the installation surface of the lower jig 10 is not limited to this example. For example, the lower jig 10 may include a stopper such as rubber attached to the second surface 104 of the first block portion 100 instead of the pedestal portion 150. The lower jig 10 does not have to have the pedestal portion 150 as long as the lower jig 10 can be stably installed without using the pedestal portion 150.

FIG. 2 is an exploded perspective view of the probe head 300 shown in FIG. 1. FIG. 3 is a perspective view of the pin block 310 shown in FIG. 2 as viewed from a viewpoint opposite to the viewpoint in FIG. 2.

The probe head 300 has the pin block 310, a pin plate 320, a probe 330, and a frame 340. A plurality of first stepped holes 312 are formed in the pin block 310. A plurality of second stepped holes 322 are formed in the pin plate 320. The plurality of first stepped holes 312 and the plurality of second stepped holes 322 extend in the third direction Z. A plurality of probes 330 (not shown in FIGS. 2 and 3) are inserted into the plurality of first stepped holes 312 and the plurality of second stepped holes 322.

The pin block 310 and the pin plate 320 are attached to the frame 340. The frame 340, the pin block 310, and the pin plate 320 are arranged in this order from the negative direction of the third direction Z toward the positive direction of the third direction Z.

Two third openings 342 are formed on the frame 340. Two protrusions 314 are formed on the pin block 310. The frame 340 is provided with two positioning pins 348. The pin block 310 is provided with two positioning holes 318. When the pin block 310 is installed on the frame 340, the two positioning pins 348 of the frame 340 enter the two positioning holes 318 of the pin block 310, and the two protrusions 314 of the pin block 310 enter the two third openings 342 of the frame 340. That is, the two positioning pins 348 of the frame 340 and the Positioning holes 318 of the pin block 310 may function as guide members for the two protrusions 314 of the pin block 310 to enter the two third openings 342 of the frame 340. Each of the number of positioning holes 318 and the number of positioning pins 348 may not be two, but may be only one, or may be three or more.

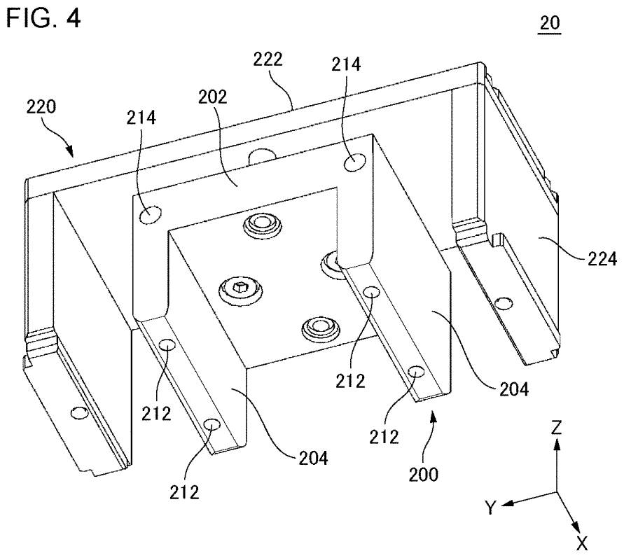

FIG. 4 is a perspective view of the upper jig 20 shown in FIG. 1 as viewed from a viewpoint opposite to the viewpoint in FIG. 1.

The second block portion 200 includes a first base 202 and two first arms 204. The first arm 204 protrudes downward (in the negative direction of the third direction Z) from the first base 202. The two first arms 204 are arranged along the second direction Y. Accordingly, the two first arms 204 may be disposed on both sides of a probe area (an area where the two protrusions 314 of the pin block 310 are disposed) in the second direction Y to avoid the probe area (the area where the two protrusions 314 of the pin block 310 are disposed) of the probe head 300. Two second suction ports 212 are formed on a lower end surface (the end surface facing in the negative direction of the third direction Z) of each first arm 204. Two second openings 214 arranged along the second direction Y are formed on a side surface of the first base 202 (a side surface directed in the negative direction of the first direction X). The two second suction ports 212 located on the left side relative to the center of the second block portion 200 and the second opening 214 located on the left side relative to the second block portion 200 when viewed from the negative direction side of the first direction X with respect to the second block portion 200 communicate with each other through a second ventilation path (not shown) provided inside the second block portion 200. The two second suction ports 212 located on the right side relative to the center of the second block portion 200 and the second opening 214 located on the right side relative to the center of the second block portion 200 when viewed from the negative direction side of the first direction X with respect to the second block portion 200 communicate with each other through the second ventilation path (not shown) provided inside the second block portion 200. The second opening 214 is connected to the decompression regulator (not shown). Accordingly, when air is sucked by the decompression regulator, air present (located) on the side where the other end (upper end) in the third direction Z of the probe 330 located opposite to the one end (lower end) is located is sucked from the second suction port 212.

The decompression regulator connected to the first suction port 112 of the first block portion 100 and the decompression regulator connected to the second suction port 212 of the second block portion 200 may be common or different.

In the present embodiment, the second block portion 200 and the support block portion 220 are made of metal. In this case, the second block portion 200 and the support block portion 220 can be stably installed at the first block portion 100 compared with a case where the first block portion 100 is made of, for example, relatively lightweight resin. However, a material forming the second block portion 200 and the support block portion 220 may be any material having a hardness such that it is not deformed by suction of air by the decompression regulator, and may be, for example, resin instead of the metal.

A shape of the second block portion 200 is not limited to the shape according to the present embodiment. For example, the second block portion 200 may have only one first arm 204, or may have three or more first arms 204. That is, the second block portion 200 may have at least one first arm 204. Alternatively, the second block portion 200 may not have the first arm 204. In this case, the second suction port 212 and the second opening 214 may be formed on, for example, the first base 202.

The support block portion 220 includes a second base 222 and two second arms 224. The two second arms 224 protrude downward (the negative direction of the third direction Z) from the second base 222. The two second arms 224 may be fixed to the first block portion 100 by a fixing tool such as a screw. The two second arms 224 are arranged along the second direction Y. The second block portion 200 is located below the support block portion 220 (the negative direction of the third direction Z), and is located between the two second arms 224 in the second direction Y.

The second block portion 200 is movably attached to the support block portion 220 in the third direction Z. In the present embodiment, a thumb screw 232 (for example, FIG. 1) penetrates through the second base 222 of the support block portion 220 and is inserted into the first base 202 of the second block portion 200. By turning the thumb screw 232 in one direction, the second block portion 200 can be moved in a direction away from the first block portion 100 (the positive direction of the third direction Z). That is, the second block portion 200 is supported by the support block portion 220 such that the second block portion 200 is movable in the direction away from the first block portion 100 (the positive direction of the third direction Z). By turning the thumb screw 232 in an opposite direction to the above one direction, the second block portion 200 can be moved in a direction toward the first block portion 100 (the negative direction of the third direction Z). That is, the second block portion 200 is supported by the support block portion 220 such that the second block portion 200 is movable in the direction toward the first block portion 100 (the negative direction of the third direction Z).

A shape of the second block portion 200 is not limited to the shape according to the present embodiment. A method of moving the second block portion 200 is not limited to the example described above.

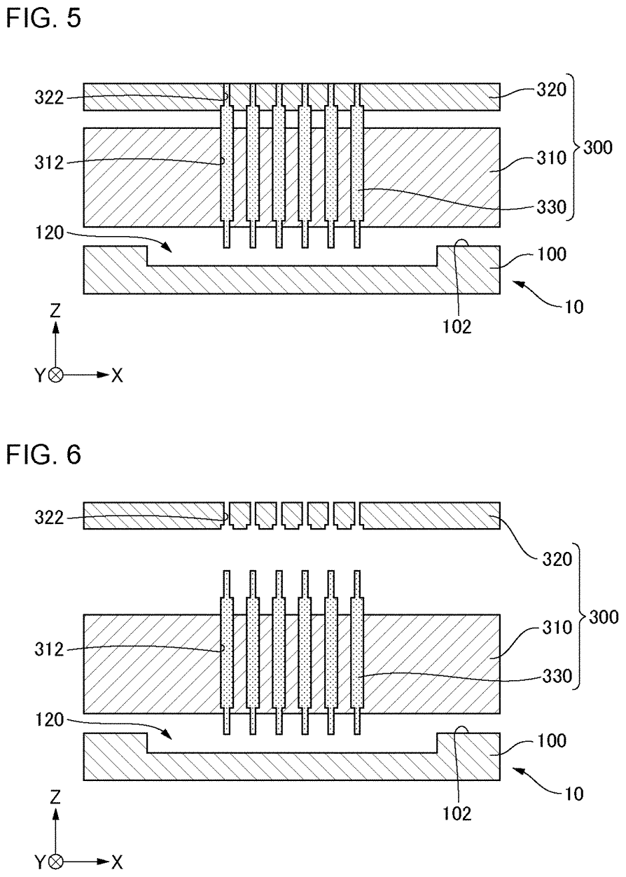

FIGS. 5 and 6 are diagrams for describing an example of an operation of the jig 30 shown in FIG. 1.

An example of a method of replacing the probe 330 will be described with reference to FIGS. 1 to 4 and by using FIGS. 5 and 6. FIGS. 5 and 6 are diagrams schematically showing a cross section of the jig 30 passing through a plurality of probes 330 along the first direction X and the third direction Z. In FIGS. 5 and 6, the pedestal portion 150 and the frame 340 are not shown. Since FIGS. 5 and 6 are schematic diagrams, the number (six) of the probes 330 in FIGS. 5 and 6 does not suggest the actual number of the plurality of probes 330 arranged along the first direction X in the probe head 300 shown in FIGS. 1 to 4.

First, as shown in FIG. 5, the probe head 300 is installed at the lower jig 10 (the first surface 102 of the first block portion 100) such that the pin block 310 is located below the pin plate 320 (the negative direction of the third direction Z). Next, the upper jig 20 (for example, FIG. 1) is installed on the lower jig 10.

Next, the decompression regulator connected to the first opening 114 (for example, FIG. 1) of the first block portion 100 is operated. Thus, air present (located) on the side where one end (lower end) in the third direction Z of the probe head 300 provided in the probe head 300 is located is sucked from the first suction port 112 (for example, FIG. 1).

Next, the decompression regulator connected to the second opening 214 of the second block portion 200 is operated. Thus, the pin plate 320 can be attracted to the lower end surface (the end surface directed in the negative direction of the third direction Z) of the first arm 204 (for example, FIG. 4) of the second block portion 200.

Next, the thumb screw 232 (for example, FIG. 1) is rotated in one direction to move the second block portion 200 (for example, FIG. 1) upward (the positive direction of the third direction Z) with respect to the support block portion 220 (for example, FIG. 1). Thus, as shown in FIG. 6, the pin plate 320 is spaced upward (the positive direction of the third direction Z) from the pin block 310. In this time, air present (located) on the side where one end (lower end) of the pin block 310 side (the negative direction side of the third direction Z) of the probe 330 is located is sucked from the first suction port 112 (for example, FIG. 1). For this reason, for example, even if the end of the probe 330 on the pin plate 320 side (the positive direction side of the third direction Z) is tilted and caught on the pin plate 320, the probe 330 can be prevented from moving toward (the positive direction of the third direction Z) upward of the pin block 310 together with the pin plate 320. In a case where the pin plate 320 is detached from the probe head 300 by moving the second block portion 200 away from the first block portion 100 (the positive direction of the third direction Z) by using the support block portion 220, for example, compared with a case where a user of the jig 30 manually detaches the pin plate 320 from the probe head 300, the efficiency of work of detaching the pin plate 320 from the probe head 300 can be improved.

Next, the probe 330 to be replaced is detached from the pin block 310. The detachment of the probe 330 from the pin block 310 is performed manually by using, for example, tweezers. Next, a new probe 330 is inserted into the first stepped hole 312 of the pin block 310 from which the probe 330 has been detached. Next, the pin plate 320 is attached to the pin block 310 such that the other end (upper end) of the probe 330 in the third direction Z is inserted into the second stepped hole 322 of the pin plate 320. Thus, the probe 330 is replaced.

In the present embodiment, as described above, when the pin plate 320 is detached from the probe head 300, the probe 330 can be prevented from moving together with the pin plate 320 upward of the pin block 310 (the positive direction of the third direction Z). Accordingly, the probe 330 not to be replaced is not detached from the pin block 310, and work of returning the probe 330 not to be replaced to the pin block 310 can be prevented from occurring. The probe 330 detached from the pin block 310 does not fall between the probe 330 and the probe 330 on the pin block 310 side, and thus troublesome for work of taking out the fallen probe 330 can be prevented. Thus, the probe 330 can be easily replaced.

Although the embodiments of the present invention have been described above with reference to the drawings, these are examples of the present invention, and various configurations other than the above configurations may be employed.

For example, in the present embodiment, the jig 30 includes both the lower jig 10 and the upper jig 20. However, the jig 30 may not include the upper jig 20. Even if the jig 30 does not include the upper jig 20, the pin plate 320 may be detached from the probe head 300, for example, manually by a user of the jig 30 while air present (located) on the side where one end (lower end) of the probe 330 in the third direction Z is located is sucked by using the lower jig 10.

In the present embodiment, air located below the probe head 300 (the negative direction of the third direction Z) is sucked from the first suction port 112. In other words, the probe head 300 is installed above the first surface 102 of the first block portion 100 (the positive direction of the third direction Z). However, instead of the air present (located) on the lower side of the probe head 300 (the negative direction of the third direction Z), for example, air present (located) on the upper side of the probe head 300 (the positive direction of the third direction Z) or the lateral side of the probe head 300 (for example, one of the positive and negative directions of the first direction X, or one of the positive and negative directions of the second direction Y) may be sucked from the first suction port 112. In other words, the probe head 300 may be installed below the first surface 102 of the first block portion 100 (the negative direction of the third direction Z) or on the lateral side of the first surface 102 of the first block portion 100 (for example, one of the positive and negative directions of the first direction X, or one of the positive and negative directions of the second direction Y).

In the present embodiment, the pin block 310 and the pin plate 320 are installed at the frame 340. However, the probe head 300 may not be installed at the frame 340. In this case, the probe head 300 may be installed directly at the first block portion 100 without using the frame 340.

According to the present specification, the following aspects are provided.

(Aspect 1)

A jig comprising:

a first block portion at which a probe head is installed; and

a first suction port formed on the first block portion,

wherein air present on a side where one end of a probe provided in the probe head is located is sucked from the first suction port.

According to aspect 1, when a pin plate is detached from the probe head, the probe can be prevented from moving together with the pin plate. Accordingly, it is possible to prevent problems caused by the probe moving with the pin plate (for example, the occurrence of unnecessary work of returning a probe not to be replaced to the pin block because the probe not to be replaced is detached from the pin block, or the occurrence of troublesome for work of taking out a fallen probe because the probe detached from the pin block falls between the probe and the probe on the pin block side). Thus, the probe can be easily replaced.

(Aspect 2)

The jig according to aspect 1, wherein

a recess is formed on the first block portion, and

the first suction port is formed on a portion of the first block portion defining the recess.

According to aspect 2, even if the probe head is warped, a gap between the first block portion and the probe head can be reduced. Accordingly, air present (located) on the side where one end of the probe provided in the probe head is located can be efficiently sucked.

(Aspect 3)

The jig according to aspect 1 or 2, wherein

the first block portion has a flexible member in contact with the probe head installed at the first block portion.

According to aspect 3, when air is sucked from the first suction port, the flexible member is pressed by the probe head such that the first block portion and the probe head can be brought into close contact with each other. Accordingly, air present (located) on the side where one end of the probe provided in the probe head is located can be efficiently sucked.

(Aspect 4)

The jig according to any one of aspects 1 to 3, wherein the first block portion has a projection inserted into the probe head installed at the first block portion.

According to aspect 4, when the probe head is installed at the first block portion, the projection can function as a guide member for guiding the probe head to an appropriate position with respect to the first block portion. Accordingly, the probe head can be guided to an appropriate position with respect to the first block portion.

(Aspect 5)

The jig according to any one of aspects 1 to 4, wherein

the first block portion has a raised portion extending along a region surrounding the probe head when the probe head is installed at the first block portion.

According to aspect 5, when the probe head is installed at the first block portion, the raised portion can function as a guide member for guiding the probe head to an appropriate position with respect to the first block portion. Accordingly, the probe head can be guided to an appropriate position with respect to the first block portion.

(Aspect 6)

The jig according to any one of aspects 1 to 5, further comprising:

a second block portion on which a second suction port is formed, wherein

air present on a side where the other end of the probe located opposite to the one end of the probe is located is sucked from the second suction port.

According to aspect 6, the pin plate can be attracted to the second block portion. Accordingly, the efficiency of work of detaching the pin plate from the probe head can be improved.

(Aspect 7)

The jig according to aspect 6, further comprising a support block portion movably supporting the second block portion.

According to aspect 7, the pin plate can be spaced apart from the pin block by moving the second block portion with respect to the support block portion. Accordingly, the efficiency of work of detaching the pin plate from the probe head can be improved.

This application claims priority based on Japanese Patent Application No. 2019-212967 filed on Nov. 26, 2019, the content of which is incorporated herein in its entirety.

### REFERENCE SIGNS LIST

10: lower jig

20: upper jig

30: jig

100: first block portion

102: first surface

104: second surface

106a: first side surface

106b: second side surface

106c: third side surface

106d: fourth side surface

108: raised portion

110: first ventilation path

112: first suction port

114: first opening

120: recess

130: flexible member

140: projection

150: pedestal portion

200: second block portion

202: first base

204: first arm

212: second suction port

214: second opening

220: support block portion

222: second base

224: second arm

232: thumb screw

300: probe head

310: pin block

312: first stepped hole

314: protrusion

316: hole

318: positioning hole

320: pin plate

322: second stepped hole

330: probe

340: frame

342: third opening

348: positioning pin

X: first direction

Y: second direction

Z: third direction

1. A jig comprising:
a first block portion at which a probe head is installed; and
a first suction port formed on the first block portion,
wherein air present on a side where one end of a probe provided in the probe head is located is sucked from the first suction port.

2. The jig according to claim 1, wherein
a recess is formed on the first block portion, and
the first suction port is formed on a portion of the first block portion defining the recess.

3. The jig according to claim 1, wherein
the first block portion has a flexible member in contact with the probe head installed at the first block portion.

4. The jig according to claim 1, wherein
the first block portion has a projection inserted into the probe head installed at the first block portion.

5. The jig according to claim 1, wherein
the first block portion has a raised portion extending along a region surrounding the probe head when the probe head is installed at the first block portion.

6. The jig according to claim 1, further comprising:
a second block portion on which a second suction port is formed, wherein
air present on a side where the other end of the probe located opposite to the one end of the probe is located is sucked from the second suction port.

7. The jig according to claim 6, further comprising:
a support block portion movably supporting the second block portion.
